(19) United States
(12) Patent Application Publication
(10) Pub. No.: US 2013/0320402 A1
(43) Pub. Date: Dec. 5, 2013

(54) pHEMT HBT INTEGRATED EPITAXIAL STRUCTURE AND A FABRICATION METHOD THEREOF

(71) Applicant: WIN SEMICONDUCTORS CORP., Kuei shan Hsiang (TW)

(72) Inventors: Shu-Hsiao TSAI, Kuei Shan Hsiang (TW); Cheng-Kuo LIN, Kuei Shan Hsiang (TW); Bing-Shan HONG, Kuei Shan Hsiang (TW); Shinichiro TAKATANI, Kuei Shan Hsiang (TW)

(73) Assignee: WIN SEMICONDUCTORS CORP., Kuei Shan Hsiang (TW)

(21) Appl. No.: 13/662,162

(22) Filed: Oct. 26, 2012

(30) Foreign Application Priority Data
Jun. 1, 2012 (TW) 101119726

(51) Int. Cl. H01L 29/778; H01L 21/335

(52) U.S. Cl. 257/194; 438/172; 438/170; 257/E29.246; 257/E21.403

(57) ABSTRACT

An improved pseudomorphic high electron mobility transistor (pHEMT) and heterojunction bipolar transistor (HBT) integrated epitaxial structure and the fabrication method thereof, in which the structure comprises a substrate, a pHEMT structure, an etching-stop spacer layer, and an HBT structure. The pHEMT's structure comprises a buffer layer, a barrier layer, a first channel spacer layer, a channel layer, a second channel spacer layer, a Schottky barrier layer, an etching-stop layer, and at least one cap layer. The fabrication method of an HBT and a pHEMT are also included.

### FIELD OF THE INVENTION

The present invention relates to an improved pseudomorphic high electron mobility transistor (pHEMT) and heterojunction bipolar transistor (HBT) integrated epitaxial structure and the fabrication method thereof, in particular to an improved pHEMT and HBT integrate depitaxial structure, in which a first and a second channel spacer layers are included above and below a channel layer respectively.

### BACKGROUND OF THE INVENTION

Pseudomorphic high electron mobility transistor (pHEMT) and heterojunction bipolar transistor (HBT) have the advantage of high efficiency, high linearity, high power density, and small size. They are important devices commonly used as microwave power amplifiers in wireless communications. Integrating the two devices in the same chip will not only lower the manufacturing cost, but also reduce necessary space for device assembling, which hence leads to reduction of the chip size.

FIG. 1 is a schematic showing the cross-sectional view for a conventional pHEMT and HBT integrated epitaxial structure. The structure comprises sequentially a substrate 101, a pHEMT structure 170, an etching-stop spacer layer 119, and an HBT structure 180. The pHEMT structure 170 comprises a buffer layer 103, a first δ-doped layer (planar doping sheet layer) 105, a barrier layer 107, a channel layer 109, a Schottky barrier layer 111, a second δ-doped layer 113, an etching-stop layer 115, and a contact layer 117, in which the buffer layer 103 is formed on the substrate 101; the first δ-doped layer 105 is formed on the buffer layer 103; the barrier layer 107 is formed on the first δ-doped layer 105; the channel layer 109 is formed on the barrier layer 107; the Schottky barrier layer 111 is formed on the channel layer 109; the second δ-doped layer 113 is formed on the Schottky barrier layer 111; the etching-stop layer 115 is formed on the second δ-doped layer 113; and the contact layer 117 is formed on etching-stop layer 115. The HBT structure 180 comprises a collector layer 121, a base layer 123, an emitter layer 125, an emitter contact layer 127, in which the collector layer 121 is formed on etching-stop spacer layer 119; the base layer 123 is formed on the collector layer 121; the emitter layer 125 is formed on the base layer 123; and the emitter contact layer 127 is formed on the emitter layer 125. The epitaxial structure provided by the conventional technology can be used to form pHEMT and HBT accordingly. In the conventional pHEMT structure 170, two δ-doped layers are employed. The two δ-doped layers are for the improvement of the output current and the power gain and lower the resistance of a pHEMT. However, the performance of the pHEMT made of the epitaxial structure still needs further improvement for application.

In view of these facts and for overcoming the drawbacks stated above, the present invention provides an improved pHEMT and HBT integrated epitaxial structure and a fabrication method thereof. The device and the fabrication method according to the present invention can lower the resistance more effectively. When employed as switch elements, it can provide the switch with low insertion loss and reduce the device size. Furthermore, the fabrication process for the device can provide a high stability and reliability.

### SUMMARY OF THE INVENTION

The main object of the present invention is to provide an improved pseudomorphic high electron mobility transistor (pHEMT) and heterojunction bipolar transistor (HBT) integrated epitaxial structure, in which a first channel spacer layer and a second channel spacer layer are included above and below a channel layer. By changing the thickness of the channel layer, the first channel spacer layer, and the second channel spacer layer of the structure, a transistor structure with required characteristics properties can be provided. In the channel layer, compound semiconductor alloy InₓGa₁₋ₓAs is used. By raising the In content x in InₓGa₁₋ₓAs, the resistance can be lowered. By using GaAs in the first channel spacer layer and the second channel spacer layer, the electric field of the gate can be dispersed, and then the on-resistance can be lowered. When used in a switching device, the structure can provide the device with the advantage of the low insertion loss, the reduced device size, the stable fabrication process and high device reliability.

To reach the objects stated above, the present invention provides an improved pHEMT structure, which comprises from bottom to top sequentially a substrate, a buffer layer, a barrier layer, a first channel spacer layer, a channel layer, a second channel spacer layer, a Schottky barrier layer, an etching-stop layer, at least a cap layer, a gate recess formed by etching the structure on the Schottky barrier layer, a gate electrode disposed in the gate recess on the Schottky barrier layer, a base electrode disposed on one end of the base layer, a drain electrode disposed on one end of the cap layer, and a source electrode disposed on the other end of the cap layer.

The present invention also provides a fabrication method of an improved pHEMT structure, which includes the following steps:

Forming sequentially on a substrate a buffer layer, a barrier layer, a first channel spacer layer, a channel layer, a second channel spacer layer, a Schottky barrier layer, an etching-stop layer, and at least one cap layer;

Forming a gate recess by first defining a gate recess region using photolithography, and then etching the cap layer and terminating the etching process at the etching-stop layer, and finally etching the etching-stop layer and terminating the etching process at the Schottky barrier layer;

Depositing a gate electrode in the gate recess on the Schottky barrier layer, and forming an ohmic contact between the gate electrode and the Schottky barrier layer.

In implementation, a drain electrode can be deposited on one end of the cap layer and forms an ohmic contact to the cap layer, and a source electrode can be deposited on another end of the cap layer and forms an ohmic contact to the cap layer in the above structure and method.

In implementation, the channel layer stated above is made of InₓGa₁₋ₓAs compound semiconductor with the In content 0<x<0.5, more preferably with the In content 0.3<x<0.4.

In implementation, the thickness of the channel layer stated above is between 10 Å and 300 Å.

In implementation, the first channel spacer layer and the second channel spacer layer stated above are formed of GaAs.

In implementation, the thickness of the first channel spacer layer and the thickness of the second channel spacer layer stated above are between 10 Å and 200 Å, more preferably between 20 Å and 70 Å.

The present invention also provides an improved pHEMT and HBT integrated epitaxial structure, which include from bottom to top sequentially a substrate, a pHEMT structure, an etching-stop spacer layer, and an HBT structure. The pHEMT structure includes from bottom to top sequentially a substrate, a buffer layer, a barrier layer, a first channel spacer layer, a channel layer, a second channel spacer layer, a Schottky barrier layer, an etching-stop layer, and at least a cap layer. The HBT structure includes from bottom to top sequentially a sub-collector layer, a collector layer, a base layer, an emitter layer, and an emitter cap layer.

The present invention further provides a fabrication method of an improved pHEMT and HBT integrated epitaxial structure, which includes the following steps:

Forming sequentially on a substrate a pHEMT structure, an etching-stop spacer layer, and an HBT structure, wherein said pHEMT structure comprises from bottom to top sequentially a buffer layer, a barrier layer, a first channel spacer layer, a channel layer, a second channel spacer layer, a Schottky barrier layer, an etching-stop layer, and at least one cap layer, and the HBT structure includes from bottom to top sequentially a sub-collector layer, a collector layer, a base layer, an emitter layer, and an emitter cap layer;

Defining a pHEMT etching region by photolithography, and first etching the HBT structure and terminating the etching process at the etching-stop spacer layer; etching the etching-stop spacer layer and terminating the etching process at the cap layer; defining a gate recess region on the pHEMT etching region by photolithography, and then etching the cap layer and terminating the etching process at the etching-stop layer; forming a gate recess by etching the etching-stop layer and terminating the etching process at the Schottky barrier layer; depositing a gate electrode in the gate recess on the Schottky barrier layer, and forming an ohmic contact between the gate electrode and the Schottky barrier layer.

Defining a base electrode contact region by photolithography; etching the base electrode contact region and terminating the etching process at said base layer; defining a collector electrode contact region on the base electrode contact region by photolithography; etching the collector electrode contact region and terminating the etching process at the sub-collector layer; depositing a collector electrode in the collector electrode contact region on the sub-collector layer and forming an ohmic contact between the collector electrode and the sub-collector layer; depositing a base electrode on the base electrode contact region on the base layer and forming an ohmic contact between the base electrode and the base layer; depositing an emitter electrode on one end of the emitter cap layer.

In implementation, a drain electrode can be deposited on one end of the cap layer and forms an ohmic contact to the cap layer, and a source electrode can be deposited on another end of the cap layer and forms an ohmic contact to the cap layer in the structure and method stated above.

In implementation, an ohmic contact can be formed between the emitter electrode and the emitter cap layer in the structure and method stated above.

In implementation, a emitter contact layer can be further included between the emitter electrode and the emitter cap layer in the structure and method stated above, and an ohmic contact can be formed between the emitter electrode and the emitter contact layer. At least one etching process of the emitter contact layer is then included in the etching process of the base electrode contact region.

In implementation, the channel layer stated above is made of InₓGa₁₋ₓAs compound semiconductor material with the In content 0<x<0.5, more preferably with the In content 0.3<x<0.4.

In implementation, the thickness of the channel layer stated above is between 10 Å and 300 Å.

In implementation, the first channel spacer layer and the second channel spacer layer stated above are formed of GaAs.

In implementation, the thickness of the first channel spacer layer and the thickness of the second channel spacer layer stated above are between 10 Å and 200 Å, more preferably between 20 Å and 70 Å.

For further understanding the characteristics and effects of the present invention, some preferred embodiments referred to drawings are in detail described as follows.

### BRIEF DESCRIPTION OF DRAWINGS

FIG. 1 is a schematic showing the cross-sectional view of a conventional pHEMT and HBT epitaxial structure.

FIG. 2˜4 are schematics showing the cross-sectional views of an improved pHEMT structure according to the embodiments provided by the present invention.

FIG. 5˜16 are schematics showing the cross-sectional views of an improved pHEMT and HBT epitaxial structure according to the embodiments provided by the present invention.

FIG. 17 is a flow chart of the fabrication method of the improved pHEMT and HBT epitaxial structure according to an embodiment provided by the present invention

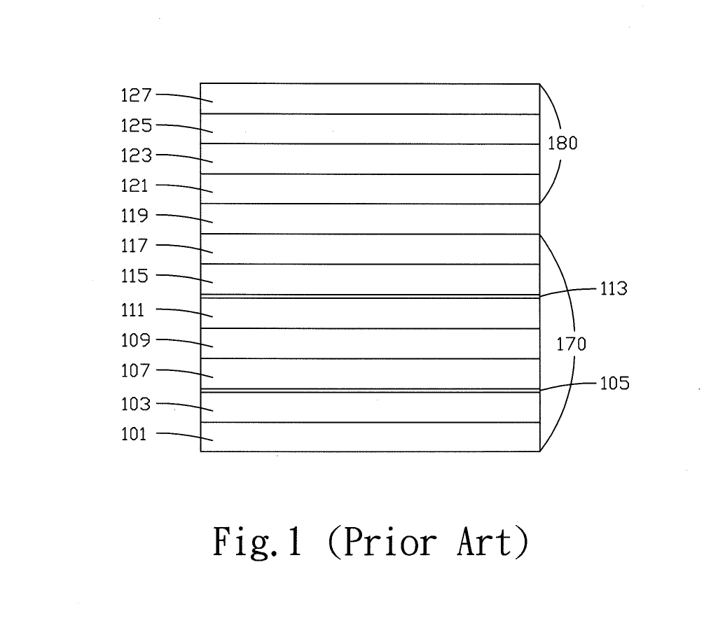

### DETAILED DESCRIPTIONS OF PREFERRED EMBODIMENTS

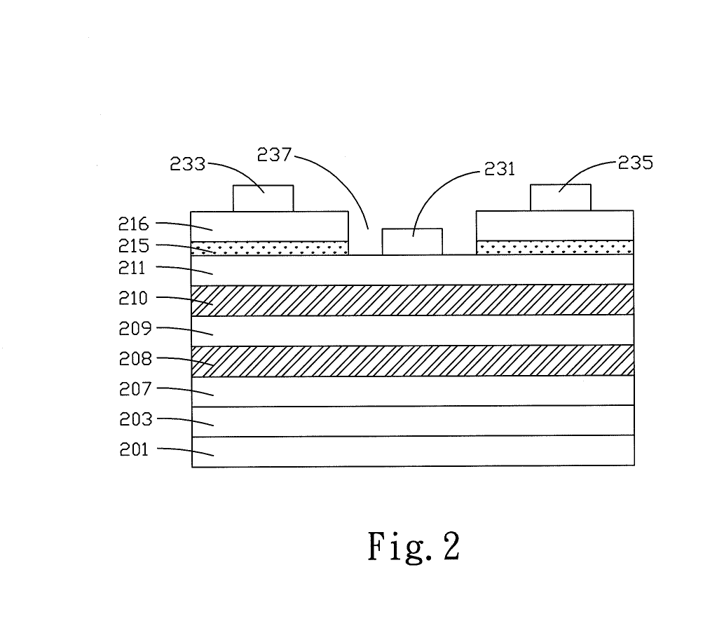

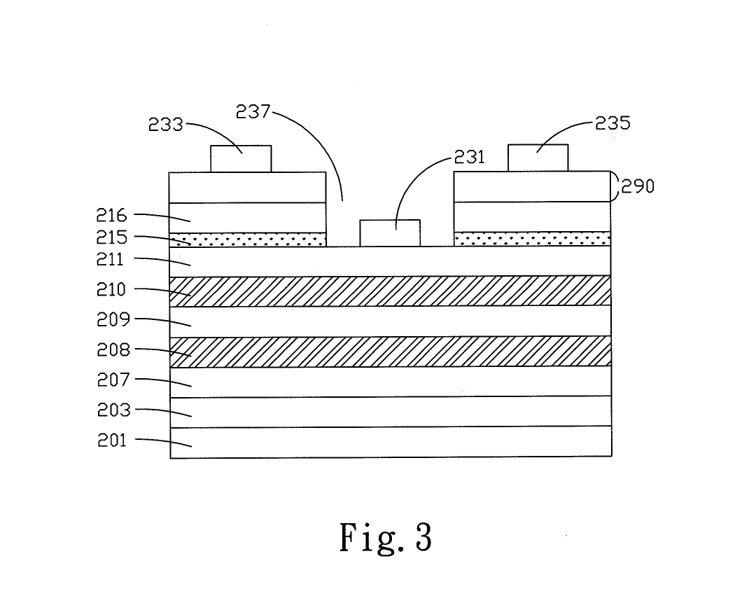

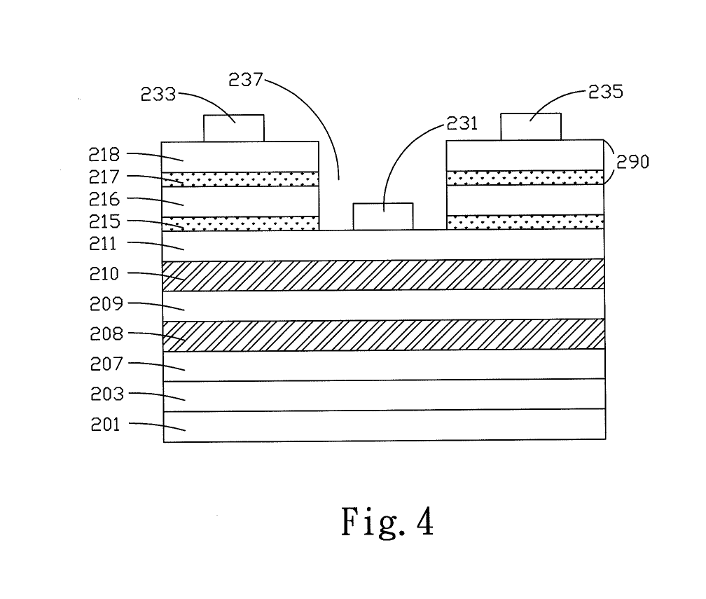

FIG. 2 is a schematic showing the cross-sectional view of an improved pHEMT structure, which comprises a substrate 201, a buffer layer 203, a barrier layer 207, a first channel spacer layer 208, a channel layer 209, a second channel spacer layer 210, a Schottky barrier layer 211, an etching-stop layer 215, at least one cap layer 216, a gate electrode 231, a drain electrode 233, a source electrode 235, and a gate recess 237.

In the structure of the present invention, the substrate 201 is preferably a semi-insulating GaAs substrate. The buffer layer 203 is formed on the substrate 201. The buffer layer 203 can be made of AlGaAs or GaAs, and preferably a combination of an undoped AlGaAs layer and an undoped GaAs layer. The barrier layer 207 is formed on the buffer layer 203. The barrier layer 207 can be made of AlGaAs, and preferably a combination of plural undoped AlGaAs layers and n-type doped AlGaAs layers. The first channel spacer layer 208 is formed on the barrier layer 207. The first channel spacer layer 208 can be made of GaAs, and preferably an undoped GaAs, and the thickness of the first channel spacer layer 208 is usually between 10 Å and 200 Å, preferably between 20 Å and 70 Å. The channel layer 209 is formed on the first channel spacer layer 208. The channel layer 209 is made preferably of InₓGa₁₋ₓAs with the In content 0<x<0.5, more preferably with the In content 0.3<x<0.4, and the thickness of the channel layer 209 is usually between 10 Å and 300 Å. The second channel spacer layer 210 is formed on the channel layer 209. The second channel spacer layer 210 can be made of GaAs, and preferably an undoped GaAs, and the thickness of the first channel spacer layer 208 is usually between 10 Å and 200 Å, preferably between 20 Å and 70 Å. The Schottky barrier layer 211 is formed on the second channel spacer layer 210. The Schottky barrier layer 211 can be made of AlGaAs, and preferably a combination of plural undoped AlGaAs layers and n-type doped AlGaAs layers. The etching-stop layer 215 is formed on the Schottky barrier layer 211, and it is made preferably of AlAs or InGaP. The cap layer 216 is formed on the etching-stop layer 215. The cap layer 216 can be made of GaAs, AlₓGa₁₋ₓAs, InₓAl₁₋ₓAs, InₓGa₁₋ₓAs, or InAlGaAs, and preferably a combination of plural layers made of the materials described previously. A gate recess 237 is formed by first defining the position and area of a gate recess region using photolithography, and then by etching the cap layer 216 and terminating the etching process at the etching-stop layer 215. The etching process can either be a wet etching or a dry etching, as long as the etching selectivity is good. In wet etching, for example, if the cap layer 216 is made of GaAs, the suitable etchants can be citric acid, succinic acid, or acetic acid. The gate recess 237 is finally formed by etching the etching-stop layer 215 and terminating the etching process at the Schottky barrier layer 211. The etching process can either be a wet etching or a dry etching as well, as long as the etching selectivity is good. In wet etching, for example, NH₄OH, H₂O₂, or HCl solution are suitable etchants for AlAs, and HCl solution is suitable etchant for InGaP. A gate electrode 231 is deposited in the gate recess 237 on the Schottky barrier layer 211, and an ohmic contact is formed between the gate electrode 237 and said Schottky barrier layer 211. A drain electrode 233 is deposited on one end of the cap layer 216, and an ohmic contact is formed between the drain electrode 233 and the cap layer 216. A source electrode 235 is deposited on another end of the cap layer 216, and an ohmic contact is formed between the source electrode 235 and the cap layer 216.

FIG. 3 is a schematic showing the cross-sectional view of another embodiment of the present invention. The structure is mostly same to the embodiment shown in FIG. 2, except that at least one upper stacked cap layer 290 is disposed on the cap layer 216 positioning between the cap layer 216 and the drain electrode 233 and between the cap layer 216 and the source electrode 235. The upper stacked cap layer 290 includes at least one stacked cap layer, which can be made of GaAs, AlₓGa₁₋ₓAs, InₓAl₁₋ₓAs, InₓGa₁₋ₓAs, or InAlGaAs, and preferably a combination of plural layers made of the materials described previously. The etching process before etching the cap layer 216 further includes etching the upper stacked cap layer 290 and terminating the etching process at the cap layer 216. Then the cap layer 216 is etched. The etching process can be either a wet etching or a dry etching, as long as the etching selectivity is good. In wet etching, for example, if the stacked cap layer of the upper stacked cap layer 290 is made of GaAs, the suitable etchants can be citric acid, succinic acid, or acetic acid. A drain electrode 233 is deposited on one end of the upper stacked cap layer 290, and an ohmic contact between the drain electrode 233 and the upper stacked cap layer 290 is formed. A source electrode 235 is deposited on another end of the upper stacked cap layer 290, and an ohmic contact between the source electrode 235 and the upper stacked cap layer 290 is formed.

FIG. 4 is a schematic showing the cross-sectional view of another embodiment of the present invention. The structure is mostly same to the embodiment shown in FIG. 3, except that a stacked etching-stop layer 217 is disposed in the structure of the upper stacked layer 290 below the stacked cap layer 218. The stacked etching-stop layer 217 is made preferably of AlAs or InGaP. An additional etching process of the stacked etching-stop layer 217 has to be included in the etching process of the upper stacked layer 290. The etching process can be either a wet etching or a dry etching, as long as the etching selectivity is good. In wet etching, for example, NH₄OH, H₂O₂, or HCl solution are suitable etchants for AlAs, and HCl solution is suitable etchant for InGaP.

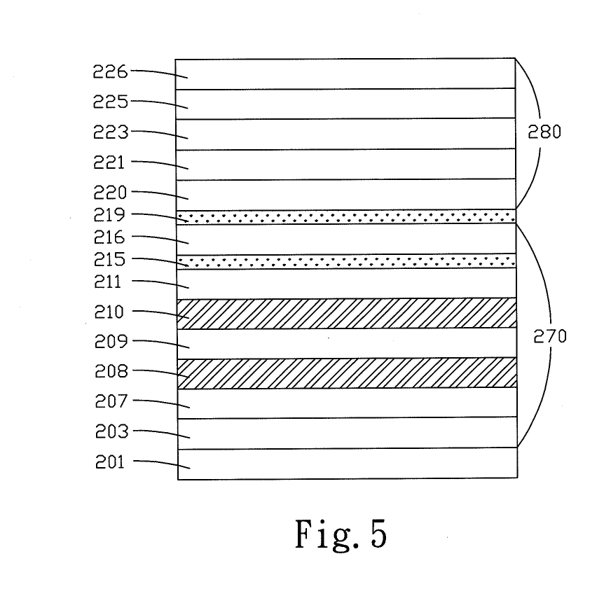

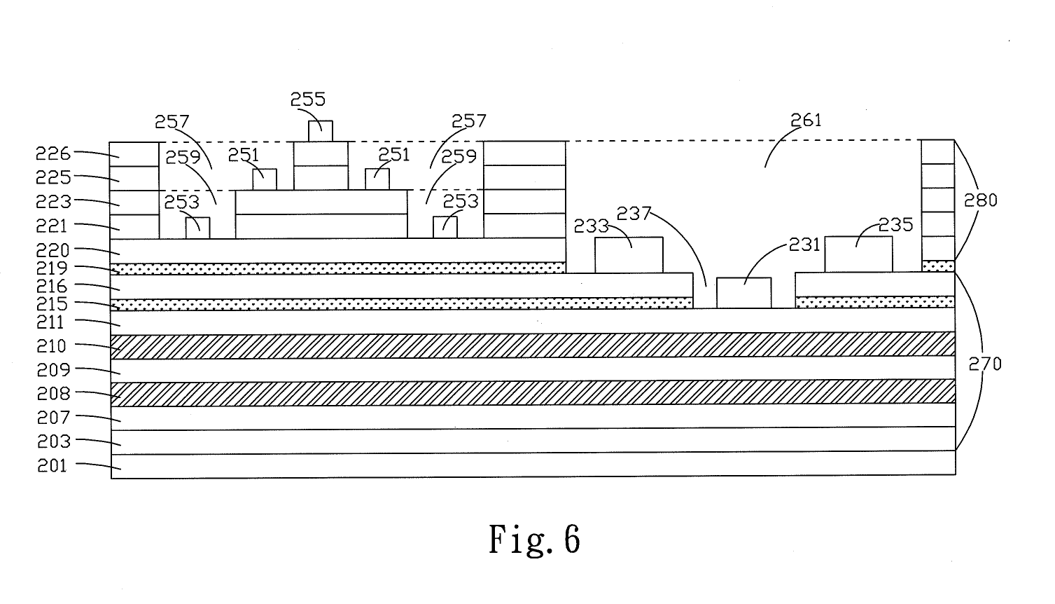

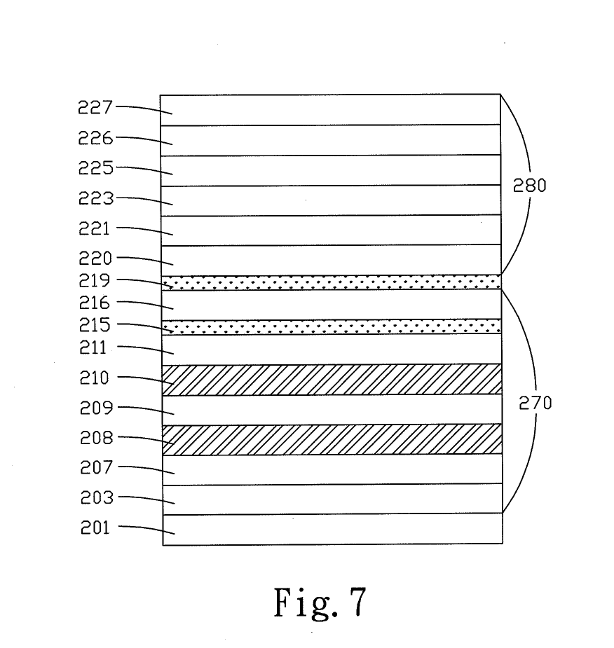

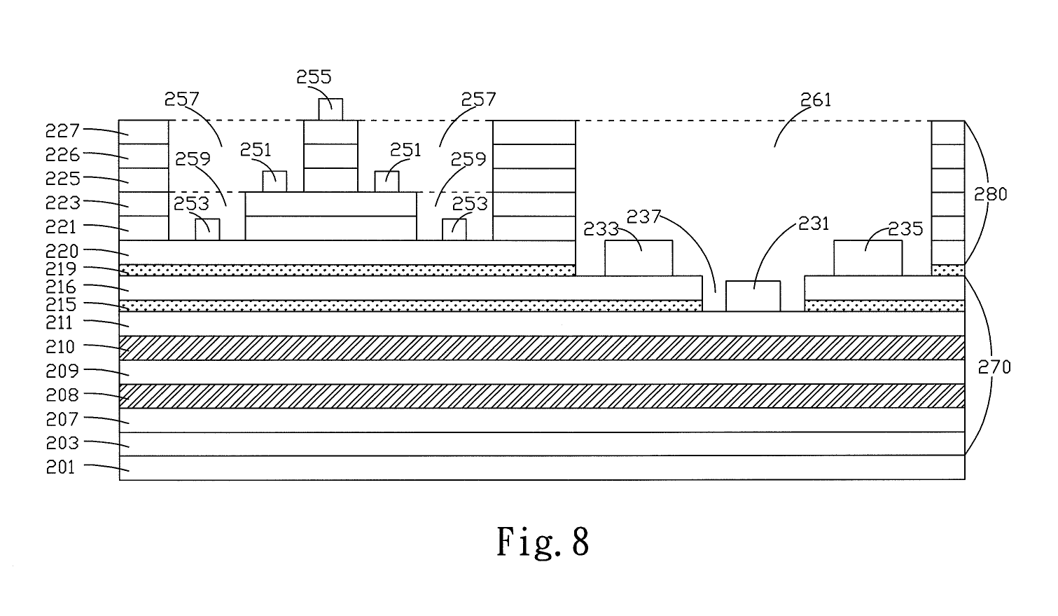

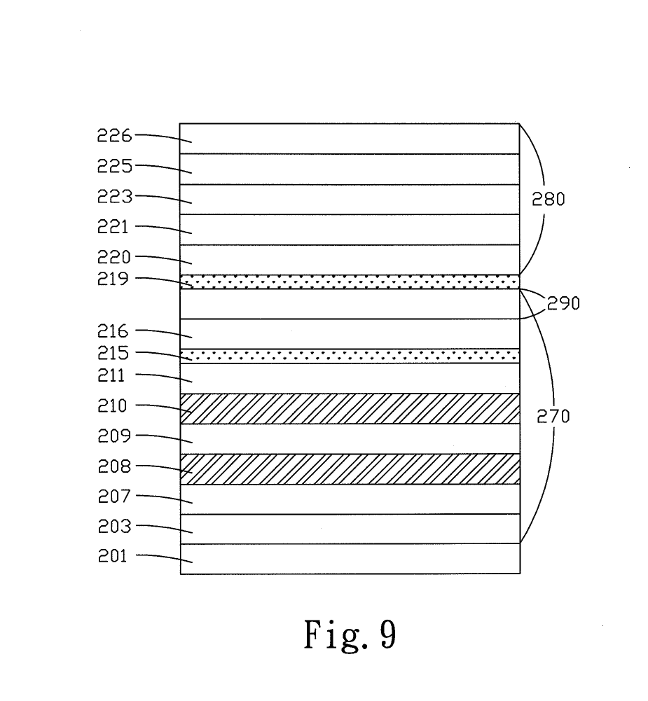

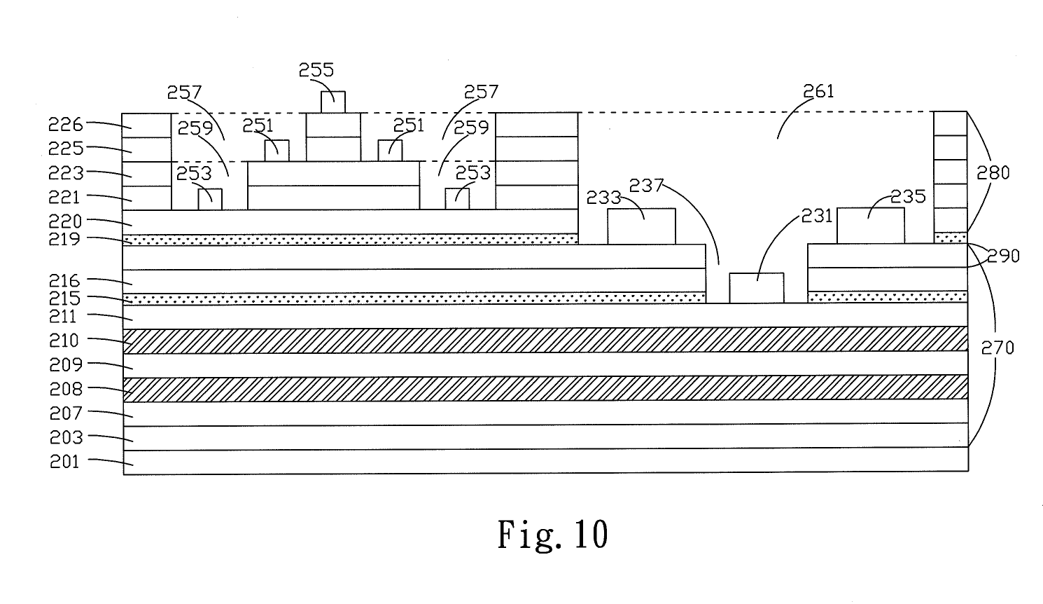

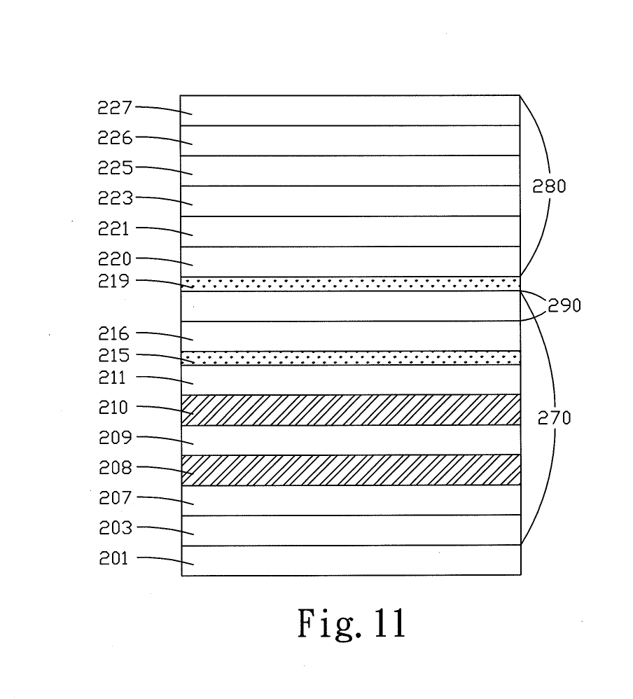

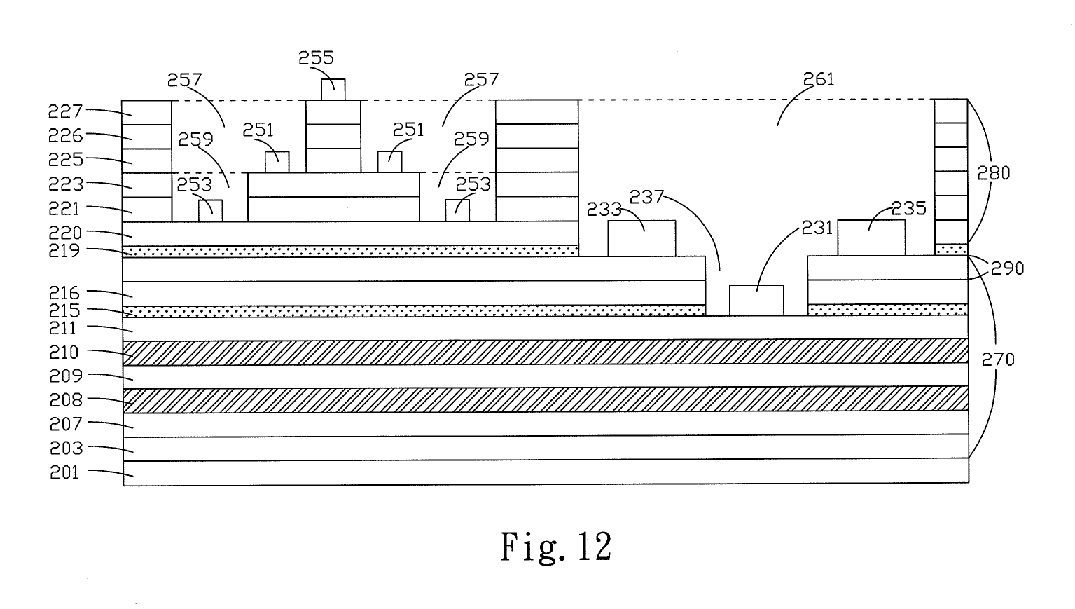

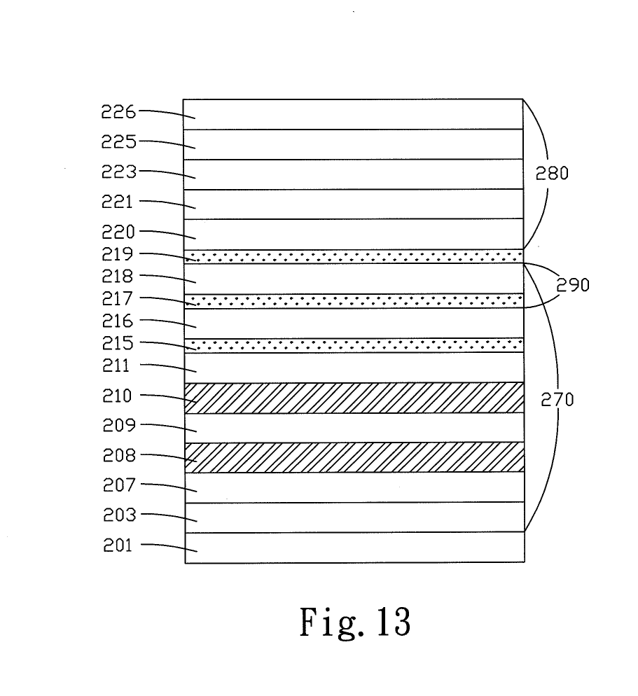

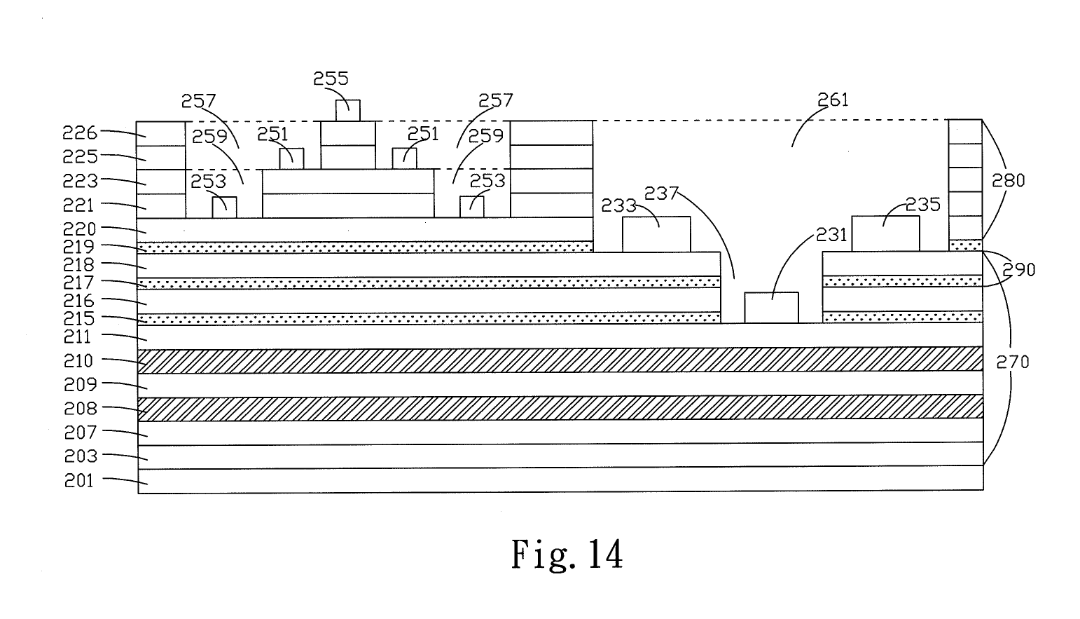

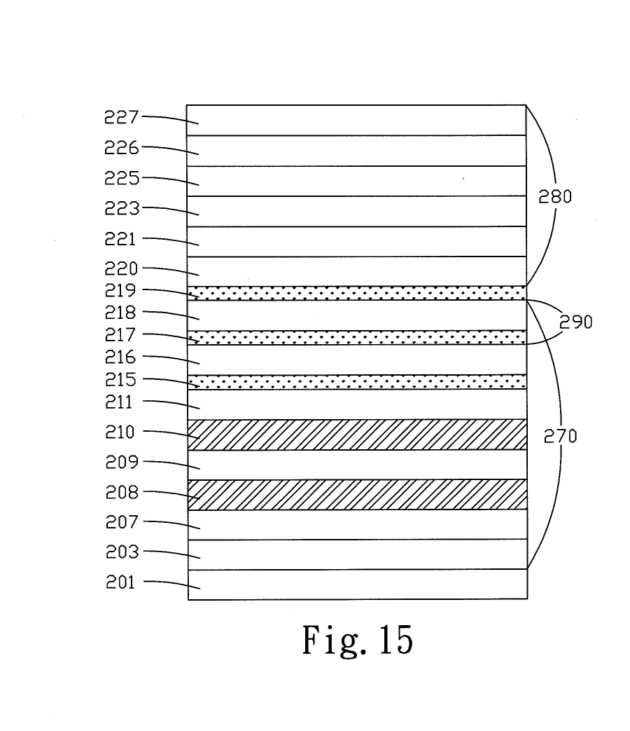

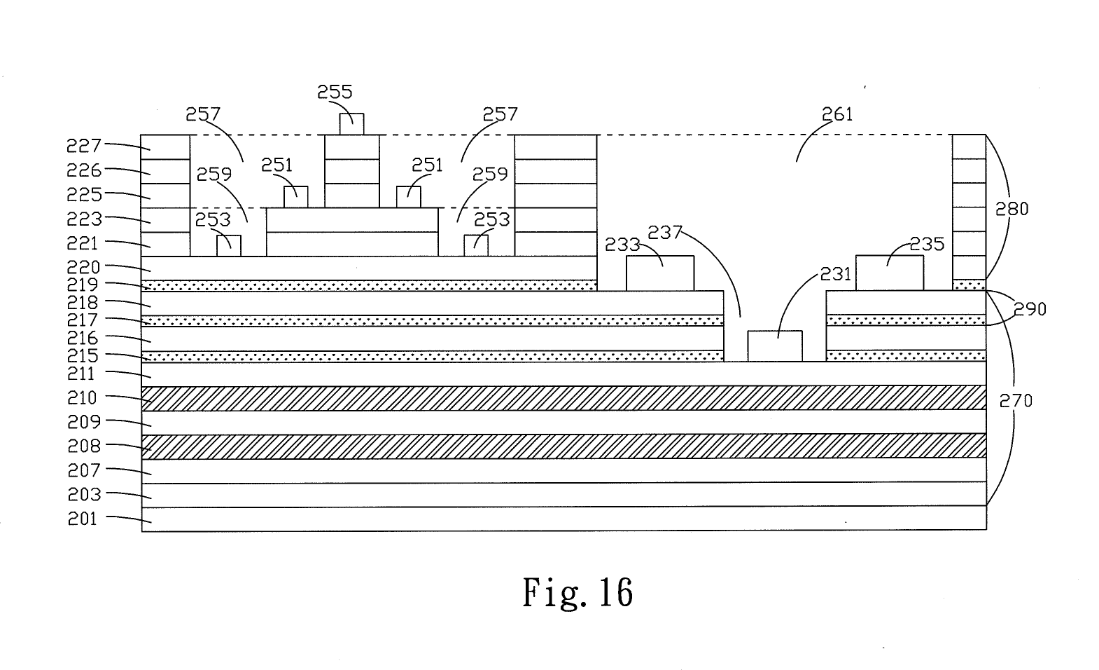

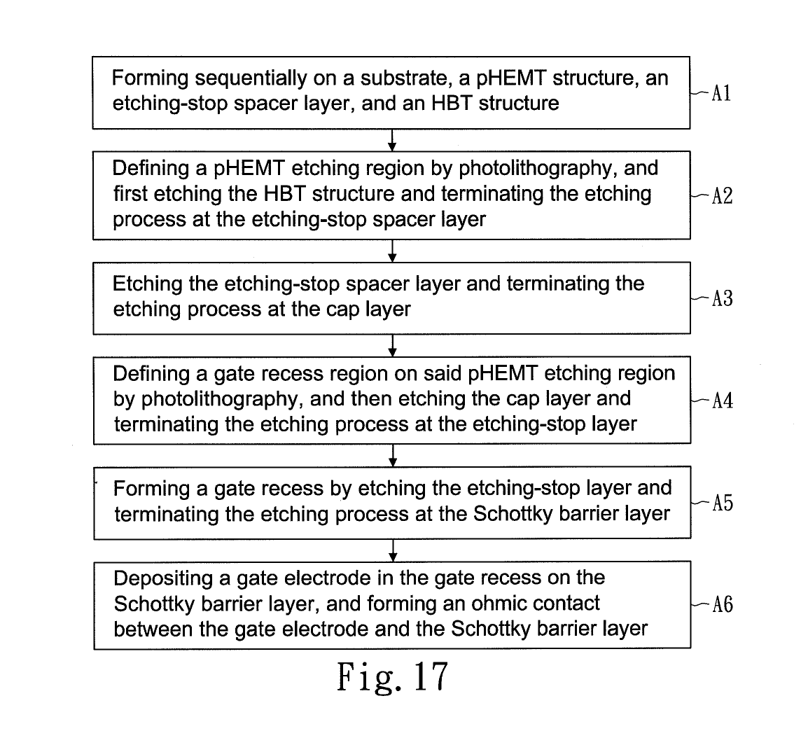

FIG. 5 is a schematic showing the cross-sectional view of an embodiment of an improved pHEMT and HBT integrated epitaxial structure provided by the present invention. The structure comprises a substrate 201, a pHEMT structure 270, an etching-stop spacer layer 219, and an HBT structure 280. The fabrication steps of an HBT and a pHEMT are also included. The pHEMT structure 270 is mostly same to the structure shown in FIG. 2, which comprises a buffer layer 203, a barrier layer 207, a first channel spacer layer 208, a channel layer 209, a second channel spacer layer 210, a Schottky barrier layer 211, an etching-stop layer 215, and at least one cap layer 216. The etching-stop spacer layer 219 is formed on the pHEMT structure 270, and it is formed preferably of AlAs or InGaP. The HBT structure 280 comprises a sub-collector layer 220, a collector layer 221, a base layer 223, an emitter layer 225, and an emitter cap layer 226. The sub-collector layer 220 is formed on the etching-stop layer 219, and it is made preferably of undoped GaAs or n+ type Si doped GaAs. The collector layer 221 is formed on the sub-collector layer 220, and it is made preferably of n-type doped GaAs with the preferable dopant Si or similar materials. The base layer 223 is formed on the collector layer 221, and it is made preferably of p-type doped GaAs with the preferable dopant carbon or similar materials. The emitter layer 225 is formed on the base layer 223, and it is made preferably of n-type doped InGaP with the preferable dopant Si or similar materials. The emitter cap layer 226 is formed on the emitter layer 225, and it is made preferably of n-type doped GaAs with the preferable dopant Si or similar materials. FIG. 6 is a schematic showing the cross-sectional view of an embodiment provided by the present invention. The fabrication steps for the HBT shown in FIG. 6 includes: Defining a base electrode contact region 257 by photolithography; first etching the emitter cap layer 226 in the base electrode contact region 257 and terminating the etching process at the emitter layer 225, in which the etching process can be either a wet etching or a dry etching, as long as the etching selectivity is good. In wet etching, for example, the suitable etchants for GaAs can be citric acid, succinic acid, or acetic acid; Etching the emitter layer 225 in the base electrode contact region 257 and terminating the etching process at the base layer 223, in which the etching process can be either a wet etching or a dry etching as well, as long as the etching selectivity is good; Defining a collector electrode contact region 259 on the base electrode contact region 257 by photolithography, and then etching the base layer 223 in the collector electrode contact region 259 and terminating the etching process at the collector layer 221, in which the etching process can be either a wet etching or a dry etching, as long as the etching selectivity is good. In wet etching, for example, the suitable etchants for GaAs can be citric acid, succinic acid, or acetic acid; Etching the collector layer 221 in the collector electrode contact region 259 and terminating the etching process at the sub-collector layer 220, in which the etching process can be either a wet etching or a dry etching as well, as long as the etching selectivity is good; Depositing a collector electrode 253 on the sub-collector layer 220 in the collector electrode contact region 259, and forming an ohmic contact between the collector electrode 253 and the sub-collector layer 220; Depositing a base electrode 251 on the base layer 223 in the base electrode contact region 259, and forming an ohmic contact between the base electrode 251 and the base layer 223; Depositing an emitter electrode 255 on one end of the emitter cap layer 226, and forming an ohmic contact between the emitter electrode 255 and the emitter cap layer 226. The fabrication steps for the pHEMT shown in FIG. 6 is as the flow chart shown in FIG. 17, which includes: Defining a pHEMT etching region 261 by photolithography; First etching the HBT structure 280 by sequentially etching the emitter cap layer 226, the emitter layer 225, the base layer 223, the collector layer 221, and the sub-collector layer 220, and terminating the etching process at the etch stop spacer layer 219; Etching the etch stop spacer layer 219 and terminating the etching process at the cap layer 216, in which the etching process can be either a wet etching or a dry etching, as long as the etching selectivity is good. In wet etching, for example, NH₄OH, H₂O₂, or HCl solution are suitable etchants for AlAs, and HCl solution is suitable etchant for InGaP; Defining a gate recess region on the pHEMT etching region 261 by photolithography, and then etching the cap layer 216 and terminating the etching process at the etching-stop layer 215; Forming a gate recess by etching the etching-stop layer 215 in the pHEMT etching region 261 and terminating the etching process at the Schottky barrier layer 211; Depositing a gate electrode 231 in the gate recess 237 on the Schottky barrier layer 211, and forming an ohmic contact between the gate electrode 231 and the Schottky barrier layer 211; Depositing a drain electrode 233 on one end of the cap layer 216 in the pHEMT etching region 261, and forming an ohmic contact between the drain electrode 233 and the cap layer 216; Depositing a source electrode 235 on another end of the cap layer 216 in the pHEMT etching region 261, and forming an ohmic contact between the source electrode 235 and the cap layer 216.

FIG. 7 is a schematic showing the cross-sectional view of another embodiment provided by the present invention. The structure is mostly same to the embodiment shown in FIG. 3, except that an emitter contact layer 227 is further included on the emitter cap layer 226 positioning between the emitter cap layer 226 and the emitter electrode 255. The emitter contact layer 227 is made preferably of n-type doped AlGaAs with the preferable dopant Si or similar materials. For the insertion of the emitter contact layer 227, the fabrication steps for the HBT and for the pHEMT should be modified accordingly. FIG. 8 is a schematic showing the cross-sectional view of another embodiment provided by the present invention. An additional step must be included in the fabrication steps of the HBT shown in FIG. 8 before etching the emitter cap layer 226 in the base electrode contact region 257, that is, first etching the emitter contact layer 227 in the base electrode contact region 257 and terminating the etching process at the emitter cap layer 226, and then etching the emitter cap layer 226 in the base electrode contact region 257 and forming an ohmic contact between the base electrode 255 and the emitter contact layer 227. An additional step must be included as well in the fabrication steps of the pHEMT shown in FIG. 8 before etching the HBT structure 280, that is, first etching the emitter contact layer 227 in the pHEMT etching region 261 and terminating the etching process at the emitter cap layer 226, and then etching the HBT structure 280 in the pHEMT etching region 261 sequentially.

FIG. 9 is a schematic showing the cross-sectional view of another embodiment of an improved pHEMT and HBT integrated epitaxial structure provided by the present invention. The structure comprises a substrate 201, a pHEMT structure 270, an etching-stop spacer layer 219, and an HBT structure 280. The fabrication steps of an HBT and a pHEMT are also included. The pHEMT structure 270 is mostly same to the structure shown in FIG. 3, which comprises a buffer layer 203, a barrier layer 207, a first channel spacer layer 208, a channel layer 209, a second channel spacer layer 210, a Schottky barrier layer 211, an etching-stop layer 215, at least one cap layer 216, and at least one upper stacked cap layer 290. The upper stacked cap layer 290 comprises at least one stacked cap layer, which is made of GaAs, AlₓGa₁₋ₓAs, InₓGa₁₋ₓAs, or InAlGaAs, and preferably a combination of plural layers made of the materials described previously. FIG. 10 is a schematic showing the cross-sectional view of another embodiment of the present invention. An additional step must be included in the fabrication steps of the HBT shown in FIG. 10 before etching the cap layer 216, that is, first etching the upper stacked cap layer 290 and terminating the etching process at the cap layer 216, and then etching the cap layer 216. The etching process can be either a wet etching or a dry etching, as long as the etching selectivity is good. The drain electrode 233 is deposited on one end of the upper stacked cap layer 290, and an ohmic contact between the drain electrode 233 and the upper stacked cap layer 290 is formed. The source electrode 235 is deposited on another end of the upper stacked cap layer 290, and an ohmic contact between the source electrode 235 and the upper stacked cap layer 290 is formed.

FIG. 11 is a schematic showing the cross-sectional view of another embodiment of the present invention. The structure is mostly same to the embodiment shown in FIG. 9, except that an emitter contact layer 227 is included on the emitter cap layer 226 positioning between the emitter electrode 255 and the emitter cap layer 226. The emitter contact layer 227 is made preferably of n-type doped AlGaAs doped with the preferable dopant Si or similar materials. For the insertion of the emitter contact layer 227, the fabrication steps for the HBT and for the pHEMT should be modified accordingly. FIG. 12 is a schematic showing the cross-sectional view of another embodiment provided by the present invention. An additional step must be included in the fabrication steps of the HBT shown in FIG. 12 before etching the emitter cap layer 226 in the base electrode contact region 257, that is, first etching the emitter contact layer 227 in the base electrode contact region 257 and terminating the etching process at the emitter cap layer 226, and then etching the emitter cap layer 226 in the base electrode contact region 257 and forming an ohmic contact between the base electrode 255 and the emitter contact layer 227. An additional step must be included as well in the fabrication steps of the pHEMT shown in FIG. 12 before etching the HBT structure 280, that is, first etching the emitter contact layer 227 in the pHEMT etching region 261 and terminating the etching process at the emitter cap layer 226, and then etching the HBT structure 280 in the pHEMT etching region 261 sequentially.

FIG. 13 is a schematic showing the cross-sectional view of another embodiment of an improved pHEMT and HBT integrated epitaxial structure provided by the present invention. The structure comprises a substrate 201, a pHEMT structure 270, an etching-stop spacer layer 219, and an HBT structure 280. The fabrication steps of an HBT and a pHEMT are also included. The pHEMT structure 270 is mostly same to the structure shown in FIG. 4, which comprises a buffer layer 203, a barrier layer 207, a first channel spacer layer 208, a channel layer 209, a second channel spacer layer 210, a Schottky barrier layer 211, an etching-stop layer 215, at least one cap layer 216, and at least one upper stacked cap layer 290. The upper stacked cap layer 290 comprises a stacked cap layer 218 and a stacked etching-stop layer 217 below the stacked cap layer 218. The stacked etching-stop layer 217 is made of AlAs or InGaP. FIG. 14 is a schematic showing the cross-sectional view of another embodiment of the present invention. As shown in the figure, an additional step for etching the stacked etching-stop layer 217 must be included before etching the upper stacked cap layer 290. The etching process can be either a wet etching or a dry etching, as long as the etching selectivity is good.

FIG. 15 is a schematic showing the cross-sectional view of another embodiment of the present invention. The structure is mostly same to the embodiment shown in FIG. 13, except that an emitter contact layer 227 is included on the emitter cap layer 226 positioning between the emitter electrode 255 and the emitter cap layer 226. The emitter contact layer 227 is made preferably of n-type doped AlGaAs doped with the preferable dopant Si or similar materials. For the insertion of the emitter contact layer 227, the fabrication steps for the HBT and for the pHEMT should be modified accordingly. FIG. 16 is a schematic showing the cross-sectional view of another embodiment provided by the present invention. An additional step must be included in the fabrication steps of the HBT shown in FIG. 16 before etching the emitter cap layer 226 in the base electrode contact region 257, that is, first etching the emitter contact layer 227 in the base electrode contact region 257 and terminating the etching process at the emitter cap layer 226, and then etching the emitter cap layer 226 in the base electrode contact region 257 and forming an ohmic contact between the base electrode 255 and the emitter contact layer 227. An additional step must be included as well in the fabrication steps of the pHEMT shown in FIG. 16 before etching the HBT structure 280, that is, first etching the emitter contact layer 227 in the pHEMT etching region 261 and terminating the etching process at the emitter cap layer 226, and then etching the HBT structure 280 in the pHEMT etching region 261 sequentially.

To sum up, the present invention indeed can get its anticipatory object that is to provide an improved pHEMT and HBT integrated epitaxial structure, in which a first channel spacer layer and a second channel spacer layer are included above and below a channel layer. The structure can disperse the electric field of the gate and lower the on-resistance significantly. When used in a switching device, the structure can provide the device with the advantage of the low insertion loss, the reduced device size, the stable fabrication process and high device reliability.

The description referred to the drawings stated above is only for the preferred embodiments of the present invention. Many equivalent local variations and modifications can still be made by those skilled at the field related with the present invention and do not depart from the spirits of the present invention, so they should be regarded to fall into the scope defined by the appended claims.

1. An improved pseudomorphic high electron mobility transistor (pHEMT) structure, comprising:
a substrate;
a buffer layer formed on said substrate;
a barrier layer formed on said buffer layer;
a first channel spacer layer formed on said barrier layer;
a channel layer formed on said first channel spacer layer;
a second channel spacer layer formed on said channel layer;
a Schottky barrier layer formed on said second channel spacer layer;
an etching-stop layer formed on said Schottky barrier layer;
at least one cap layer formed on said etching-stop layer;
a gate recess formed by using at least one etching process terminated at said Schottky barrier layer;
a gate electrode disposed in said gate recess on said Schottky barrier layer;
a drain electrode disposed on one end of said cap layer; and
a source electrode disposed on another end of said cap layer.

2. The improved pHEMT structure according to claim 1, wherein said channel layer is made of InₓGa₁₋ₓAs compound semiconductor with the In content 0<x<0.5.

3. The improved pHEMT structure according to claim 1, wherein the thickness of said channel layer is between 10 Å and 300 Å.

4. The improved pHEMT structure according to claim 1, wherein said first channel spacer layer and said second channel spacer layer are formed of GaAs.

5. The improved pHEMT structure according to claim 1, wherein the thickness of said first channel spacer layer and the thickness of said second channel spacer layer is between 10 Å and 200 Å.

6. The improved pHEMT structure according to claim 1, wherein at least one upper stacked cap layer is disposed on said cap layer, and said upper stacked cap layer is positioned between said cap layer and said drain electrode and between said cap layer and said source electrode, and said upper stacked cap layer includes
at least one stacked cap layer.

7. The improved pHEMT structure according to claim 6, wherein a stacked etching-stop layer is further included in said upper stacked cap layer below said stacked cap layer, so that said upper stacked cap layer includes
said stacked etching-stop layer; and
said stacked cap layer disposed on said stacked etching-stop layer.

8. A fabrication method of an improved pHEMT structure, including the following steps:
forming sequentially on a substrate a buffer layer, a barrier layer, a first channel spacer layer, a channel layer, a second channel spacer layer, a Schottky barrier layer, an etching-stop layer, and at least one cap layer;
forming a gate recess by first defining a gate recess region using photolithography, and then etching said cap layer and terminating the etching process at said etching-stop layer, and finally etching said etching-stop layer and terminating the etching process at said Schottky barrier layer; and
depositing a gate electrode in said gate recess on said Schottky barrier layer, and forming an ohmic contact between said gate electrode and said Schottky barrier layer.

9. The fabrication method of an improved pHEMT structure according to claim 8, wherein said channel layer is made of InₓGa₁₋ₓAs compound semiconductor with the In content 0<x<0.5.

10. The fabrication method of an improved pHEMT structure according to claim 8, wherein the thickness of said channel layer is between 10 Å and 300 Å.

11. The fabrication method of an improved pHEMT structure according to claim 8, wherein said first channel spacer layer and said second channel spacer layer are formed of GaAs.

12. The fabrication method of an improved pHEMT structure according to claim 8, wherein the thickness of said first channel spacer layer and the thickness of said second channel spacer layer is between 10 Å and 200 Å.

13. The fabrication method of an improved pHEMT structure according to claim 8, wherein a drain electrode is deposited on one end of said cap layer, and an ohmic contact is formed between said drain electrode and said cap layer; a source electrode is deposited on another end of said cap layer, and an ohmic contact is formed between said source electrode and said cap layer.

14. The fabrication method of an improved pHEMT structure according to claim 8, wherein
at least one upper stacked cap layer is disposed on said cap layer, in which said upper stacked cap layer includes at least one stacked cap layer;
the etching process before etching said cap layer further includes etching said upper stacked cap layer and terminating the etching process at said cap layer;
depositing a drain electrode on one end of said upper stacked cap layer, and forming an ohmic contact between said drain electrode and said upper stacked cap layer; and
depositing a source electrode on another end of said upper stacked cap layer, and forming an ohmic contact between said source electrode and said upper stacked cap layer.

15. The fabrication method of an improved pHEMT structure according to claim 14, wherein
a stacked etching-stop layer is further included in said upper stacked cap layer below said stacked cap layer; and
the etching process of said upper stacked cap layer further includes etching said stacked etching-stop layer before etching said cap layer.

16. An improved pseudomorphic high electron mobility transistor (pHEMT) and heterojunction bipolar transistor (HBT) integrated epitaxial structure, comprising:
a substrate;
a pHEMT structure formed on said substrate, which comprises
a buffer layer,
a barrier layer formed on said buffer layer,
a first channel spacer layer formed on said barrier layer,
a channel layer formed on said first channel spacer layer,
a second channel spacer layer formed on said channel layer,
a Schottky barrier layer formed on said second channel spacer layer,
an etching-stop layer formed on said Schottky barrier layer, and
at least one cap layer formed on said etching-stop layer;
an etching-stop spacer layer formed on said pHEMT structure; and
an HBT structure formed on said etching-stop spacer layer.

17. The improved pHEMT and HBT integrated epitaxial structure according to claim 16, wherein said channel layer is made of InₓGa₁₋ₓAs compound semiconductor with the In content 0<x<0.5.

18. The improved pHEMT and HBT integrated epitaxial structure according to claim 16, wherein the thickness of said channel layer is between 10 Å and 300 Å.

19. The improved pHEMT and HBT integrated epitaxial structure according to claim 16, wherein said first channel spacer layer and said second channel spacer layer are formed of GaAs.

20. The improved pHEMT and HBT integrated epitaxial structure according to claim 16, wherein the thickness of said first channel spacer layer and the thickness of said second channel spacer layer are between 10 Å and 200 Å.

21. The improved pHEMT and HBT integrated epitaxial structure according to claim 16, wherein at least one upper stacked cap layer is disposed on said cap layer, and said upper stacked cap layer includes at least one stacked cap layer.

22. The improved pHEMT and HBT integrated epitaxial structure according to claim 21, wherein a stacked etching-stop layer is further included in said upper stacked cap layer below said stacked cap layer.

23. The improved pHEMT and HBT integrated epitaxial structure according to claim 16, wherein said HBT structure comprises:
a sub-collector layer;
a collector layer formed on said sub-collector layer;
a base layer formed on said collector layer;
an emitter layer formed on said base layer; and
an emitter cap layer formed on said emitter layer.

24. The improved pHEMT and HBT integrated epitaxial structure according to claim 23, wherein an emitter contact layer is further included on said emitter cap layer.

25. A fabrication method of an improved pHEMT and HBT integrated epitaxial structure, including the following steps:
forming sequentially on a substrate, a pHEMT structure, an etching-stop spacer layer, and an HBT structure, wherein said pHEMT structure comprises:
a buffer layer,
a barrier layer formed on said buffer layer,
a first channel spacer layer formed on said barrier layer,
a channel layer formed on said first channel spacer layer,
a second channel spacer layer formed on said channel layer,
a Schottky barrier layer formed on said second channel spacer layer,
an etching-stop layer formed on said Schottky barrier layer, and
at least one cap layer formed on said etching-stop layer;
the fabrication steps of a pHEMT structure including:
defining a pHEMT etching region by photolithography, and first etching said HBT structure and terminating the etching process at said etching-stop spacer layer;
etching said etching-stop spacer layer and terminating the etching process at said cap layer;
defining a gate recess region on said pHEMT etching region by photolithography, and then etching said cap layer and terminating the etching process at said etching-stop layer;
forming a gate recess by etching said etching-stop layer and terminating the etching process at said Schottky barrier layer; and
depositing a gate electrode in said gate recess on said Schottky barrier layer, and forming an ohmic contact between said gate electrode and said Schottky barrier layer.

26. The fabrication method of an improved pHEMT and HBT integrated epitaxial structure according to claim 25, wherein said channel layer is made of InₓGa₁₋ₓAs compound semiconductor with the In content 0<x<0.5.

27. The fabrication method of an improved pHEMT and HBT integrated epitaxial structure according to claim 25, wherein the thickness of said channel layer is between 10 Å and 300 Å.

28. The fabrication method of an improved pHEMT and HBT integrated epitaxial structure according to claim 25, wherein said first channel spacer layer and said second channel spacer layer are formed of GaAs.

29. The fabrication method of an improved pHEMT and HBT integrated epitaxial structure according to claim 25, wherein the thickness of said first channel spacer layer and the thickness of said second channel spacer layer is between 10 Å and 200 Å.

30. The fabrication method of an improved pHEMT and HBT integrated epitaxial structure according to claim 25, wherein a drain electrode is deposited on one end of said cap layer, and an ohmic contact is formed between said drain electrode and said cap layer; a source electrode is deposited on another end of said cap layer, and an ohmic contact is formed between said source electrode and said cap layer.

31. The fabrication method of an improved pHEMT and HBT integrated epitaxial structure according to claim 25, wherein
at least one upper stacked cap layer is disposed on said cap layer, wherein said upper stacked cap layer includes at least one stacked cap layer;
the etching process of said etching-stop spacer layer is terminated at said upper stacked cap layer;
defining a gate recess region on said pHEMT etching region by photolithography; etching said upper stacked cap layer and terminating the etching process at said cap layer before etching said cap layer;
depositing a drain electrode on one end of said upper stacked cap layer, and forming an ohmic contact between said drain electrode and said upper stacked cap layer; and
depositing a source electrode on another end of said upper stacked cap layer, and forming an ohmic contact between said source electrode and said upper stacked cap layer.

32. The fabrication method of an improved pHEMT and HBT integrated epitaxial structure according to claim 25, wherein
a stacked etching-stop layer is further included in said upper stacked cap layer below said stacked cap layer; and
the etching process of said upper stacked cap layer further includes etching said stacked etching-stop layer before etching said cap layer.

33. The fabrication method of an improved pHEMT and HBT integrated epitaxial structure according to claim 25, wherein said HBT structure comprises:
a sub-collector layer;
a collector layer formed on said sub-collector layer;
a base layer formed on said collector layer;
an emitter layer formed on said base layer; and
an emitter cap layer formed on said emitter layer;
wherein the fabrication steps of said HBT comprises:
defining a base electrode contact region by photolithography;
etching said base electrode contact region and terminating the etching process at said base layer;
defining a collector electrode contact region on said base electrode contact region by photolithography; etching said collector electrode contact region and terminating the etching process at said sub-collector layer;
depositing a collector electrode on said collector electrode contact region on said sub-collector layer and forming an ohmic contact between said collector electrode and said sub-collector layer;
depositing a base electrode on said base electrode contact region on said base layer and forming an ohmic contact between said base electrode and said base layer; and
depositing an emitter electrode on one end of said emitter cap layer.

34. The fabrication method of an improved pHEMT and HBT integrated epitaxial structure according to claim 33, wherein an ohmic contact is formed between said emitter electrode and said emitter cap layer is formed.

35. The fabrication method of an improved pHEMT and HBT integrated epitaxial structure according to claim 33, wherein an emitter contact layer is further included between said emitter cap layer and said emitter electrode, and an ohmic contact is formed between said emitter electrode and said emitter contact layer; at least one etching process of said emitter contact layer is further included in the etching process of said base electrode contact region.
